(19) United States
(12) Patent Application Publication
(10) Pub. No.: US 2026/0250537 A1
(43) Pub. Date: Aug. 27, 2026

(54) CONDUCTIVE INK COMPOSITION AND WIRING PATTERN

(71) Applicant: DUPONT ELECTRONICS, INC., Wilmington, DE (US)

(72) Inventors: YEN MING TSENG, HSINCHU CITY (TW); CHING MAO HUANG, HSINCHU CITY (TW); TSUNG HAN TSAI, HSINCHU CITY (TW); LI YEN LIN, HSINCHU CITY (TW)

(21) Appl. No.: 19/537,731

(22) Filed: Feb. 12, 2026

Related U.S. Application Data
(60) Provisional application No. 63/762,491, filed on Feb. 24, 2025.

(51) Int. Cl. C09D 11/52; H05K 1/09; H05K 3/12

(52) U.S. Cl. CPC C09D 11/52; H05K 1/095; H05K 3/1275; H05K 2203/105

(57) ABSTRACT

The present disclosure provides a conductive ink composition comprising silver nanoparticles, a binder and a solvent, and has good stringiness when subjected to texture test. The conductive ink composition has good operability and can be printed to produce wiring patterns.

### FIELD OF THE INVENTION

The present disclosure provides a conductive ink composition with good stringiness, and a wiring pattern manufactured from the same. The conductive ink composition and wiring pattern of the present disclosure can be applied in various fields such as printed circuit broads, displays, and advanced packaging.

### BACKGROUND OF THE INVENTION

Conventionally, a wiring pattern of an electronic circuit can be formed by photolithography, where unwanted portions of a metal layer are etched away to provide a desired pattern. However, photolithography typically involves high energy consumption, numerous production steps and a considerable amount of wasted materials.

As an alternative to photolithography, pressure-controlled direct printing has been studied and developed. In contrast to photolithography, this printing method is an additive process rather than a subtractive process and has the advantage of producing less wasted materials. Generally, pressure-controlled direct printing involves extrusion of an ink though a nozzle onto a surface of a substrate. It has been found that in this traditional printing technique, the extruded ink would become wider when touching the outer diameter of the nozzle. In view of this, the nozzle used for printing should have a smaller diameter than the width of the predetermined pattern feature. Besides, the distance between the nozzle and substrate, also referred to as the “working distance”, needs to be sufficiently close to ensure that the extruded ink is aligned in a desired shape at a predetermined location. These issues result in some limitations on the operation window for this traditional pressure-controlled direct printing technique, especially when the substrate is not sufficiently flat.

As electronic devices have become more compact and delicate, the demand for ultra-fine lines has increased dramatically. Traditional pressure-controlled direct printing techniques are failing to keep up with demand due to the aforementioned limitations. On the other hand, electrohydrodynamic (EHD) printing is an emerging technique which has gained much attention in recent years. EHD printing utilizes a voltage difference between the nozzle and substrate, allowing ink to be pulled by an electric field. Due to the driving mechanism, i.e., by electric field, the ejected ink by EHD printing may have a smaller spatial dimension and can maintain an elongated filament shape over a longer distance than in the case of traditional pressure-controlled direct printing. This allows EHD printing to adopt a bigger nozzle and a longer working distance, which broadens the operation window.

In EHD printing, functional substances such as silver nanoparticles/wires/flakes may be added to the ink to impart certain characteristics such as conductivity. These extrinsic substances may sometimes alter the rheological behavior of the ink and thus result in different operability or printability. To ensure good operability and printability, suitable ink/ink composition must be carefully selected.

### SUMMARY OF THE INVENTION

In view of the aforementioned technical problems, the present disclosure provides a conductive ink composition which has good stringiness and may provide good operability and printability.

Accordingly, an objective of the present disclosure is to provide a conductive ink composition, which comprises:
(A) 20 wt % to 95 wt % of silver nanoparticles;
(B) 0.1 wt % to 20 wt % of a binder; and
(C) 4.9 wt % to 79.9 wt % of a solvent;
wherein the wt % is based on a total weight of the conductive ink composition;
wherein the conductive ink composition has a stringiness of at least 5 mm when subjected to a texture test; and
wherein the texture test is conducted under the following conditions:
   immersing a probe with a diameter of 1 cm vertically into the conductive ink composition to a depth of 1 mm beneath a surface of the conductive ink composition,
   withdrawing the probe vertically at a speed of 1 mm/s, and
   defining stringiness as a maximum distance from the surface of the conductive ink composition at which a force exerted on the probe is 0 g.

In an embodiment of the present disclosure, the conductive ink composition has a viscosity of 2,000 to 12,000 cPs measured at 25° C. and a shear rate of 85 s⁻¹.

In an embodiment of the present disclosure, the silver nanoparticles (A) have an average diameter of 20 nm to 400 nm.

In an embodiment of the present disclosure, the binder (B) is selected from the group consisting of poly(vinyl acetate), poly(vinyl alcohol) (PVA), polydioxanone (PDO), polyacrylamide (PAM), poly(glycolic acid) (PGA), poly-(ε-caprolactone) (PCL), poly(L-lactic acid) (PLLA), polyurethane (PU), polyacrylate, polyvinylpyrrolidone (PVP), poly(vinyl alcohol-co-ethylene), polyethylene glycol (PEG), poly(tetramethylene ether) glycol (PTMEG), ethyl cellulose (EC), cellulose acetate, hydroxypropylmethyl cellulose (HPMC), polyvinyl butyral (PVB), and combinations thereof.

In an embodiment of the present disclosure, the solvent (C) is alkoxy alcohol or alkoxy ester.

In an embodiment of the present disclosure, based on a total weight of the binder (B) and silver nanoparticles (A), the amount of the binder (B) is 4 wt % to 45 wt %.

Another objective of the present disclosure is to provide a wiring pattern, which is manufactured from the aforementioned conductive ink composition.

In an embodiment of the present disclosure, the wiring pattern is manufactured by electrohydrodynamic (EHD) printing.

To render the above objectives, technical features, and advantages of the present disclosure more apparent, the present disclosure will be described in detail with reference to some embodiments hereinafter.

### BRIEF DESCRIPTION OF THE DRAWINGS

FIG. 1 is an exemplary force-distance diagram for the texture test according to the present disclosure.

FIG. 2 is a representative OM result of “well-aligned fibers” after EHD printing.

FIG. 3 is a representative OM result of “poor-aligned fibers” after EHD printing.

FIG. 4 is a representative OM result of “no fiber” after EHD printing.

### DETAILED DESCRIPTION OF THE INVENTION

Hereinafter, some embodiments of the present disclosure will be described in detail. However, the present disclosure may be embodied in various embodiments, and the protection scope of the present disclosure should not be limited to those described in the specification.

As used herein, the expressions “a”, “the”, or the like recited in the specification and in the claims should include both the singular and the plural forms unless stated otherwise.

The conductive ink composition and wiring pattern of the present disclosure are described in detail below.

### Conductive Ink Composition

In the present disclosure, the conductive ink composition comprises (A) silver nanoparticles, (B) a binder and (C) a solvent as essential components and may further comprise optional components. The components are described in detail below.

The conductive ink composition of the present disclosure comprises silver nanoparticles to impart conductivity to products made from the conductive ink composition. Among electrically conductive substances, silver is highly regarded because it has high electrical and thermal conductivity, and is relatively less expensive compared to gold nanoparticles or graphene. Additionally, silver nanoparticles have a drastically lower melting point compared to bulk silver, which may be advantageous for application to flexible substrates such as polymers and papers.

The size of the silver nanoparticles can be selected depending on the production process or further applications. For example, in cases where sintering process is involved in the further production process, the size of the silver nanoparticles can be selected for optimal absorption of the light/heat source. In an embodiment of the present disclosure, the silver nanoparticles may have an average diameter of 20 nm to 400 nm, or 50 nm to 350 nm, or 100 nm to 160 nm. For example, the average diameter of the silver nanoparticles can be 20 nm, 30 nm, 40 nm, 50 nm, 60 nm, 70 nm, 80 nm, 90 nm, 100 nm, 110 nm, 120 nm, 130 nm, 140 nm, 150 nm, 160 nm, 170 nm, 180 nm, 190 nm, 200 nm, 220 nm, 240, nm, 250 nm, 260 nm, 280 nm 300 nm, 320 nm, 340 nm, 350 nm, 360 nm, 380 nm, or 400 nm, or within a range between any two of the values described herein. The average diameter of the silver nanoparticles can be measured by using a dynamic light scattering particle size analyzer.

The amount of the silver nanoparticles can range from 20 wt % to 95 wt %, or 20 wt % to 75 wt %, or 25 wt % to 70 wt %, based on a total weight of the conductive ink composition. For example, based on the total weight of the conductive ink composition, the amount of the silver nanoparticles can be 20 wt %, 22.5 wt %, 25 wt %, 27.5 wt %, 30 wt %, 32.5 wt %, 35 wt %, 37.5 wt %, 40 wt %, 42.5 wt %, 45 wt %, 47.5 wt %, 50 wt %, 52.5 wt %, 55 wt %, 57.5 wt %, 60 wt %, 62.5 wt %, 65 wt %, 67.5 wt %, 70 wt %, 72.5 wt %, 75 wt %, 77.5 wt %, 80 wt %, 82.5 wt %, 85 wt %, 87.5 wt %, 90 wt %, 92.5 wt %, or 95 wt %, or within a range between any two of the values described herein. If the amount of the silver nanoparticles is higher than the range above, silver nanoparticles may aggregate and not well-dispersed. It may affect the operability.

The silver nanoparticles can be prepared by methods known in the art or obtained commercially. In some cases, the silver nanoparticles are obtained commercially in the form of a silver nanoparticle slurry. If desired, the silver nanoparticles may be subjected to surface treatment or modification before use.

In the present disclosure, the conductive ink composition comprises a binder. The binder can promote filament production during EHD printing, and may play a role in imparting good adhesion to substrate when the conductive ink composition is ejected onto a substrate. The binder may also facilitate the dispersion of the silver nanoparticles and prevent them from agglomeration.

The type of the binder can be selected such that the binder has good affinity with the silver nanoparticles. In cases where sintering process is involved in the further production process, the type of the binder can be selected such that the binder is partially evaporated or decomposed under the predetermined light/heat source to facilitate the sintering of the silver nanoparticles.

In an embodiment of the present disclosure, the binder can be selected from the group consisting of poly(vinyl acetate), poly(vinyl alcohol) (PVA), polydioxanone (PDO), polyacrylamide (PAM), poly(glycolic acid) (PGA), poly-(ε-caprolactone) (PCL), poly(L-lactic acid) (PLLA), polyurethane (PU), polyacrylate, polyvinylpyrrolidone (PVP), poly(vinyl alcohol-co-ethylene), polyethylene glycol (PEG), poly(tetramethylene ether) glycol (PTMEG), ethyl cellulose (EC), cellulose acetate, hydroxypropylmethyl cellulose (HPMC), polyvinyl butyral (PVB), and combinations thereof. In a more specific embodiment, the binder is selected from the group consisting of polyurethane (PU), polyacrylate, polyvinylpyrrolidone (PVP), ethyl cellulose (EC), cellulose acetate, hydroxypropylmethyl cellulose (HPMC), and combinations thereof.

The amount of the binder can range from 0.1 wt % to 20 wt %, or 2.5 wt % to 18 wt %, or 3 wt % to 15 wt %, based on a total weight of the conductive ink composition. For example, based on the total weight of the conductive ink composition, the amount of the binder can be 0.1 wt %, 0.5 wt %, 1 wt %, 2 wt %, 2.5 wt %, 3 wt %, 4 wt %, 5 wt %, 6 wt %, 7 wt %, 8 wt %, 9 wt % 10 wt %, 11 wt %, 12 wt %, 13 wt %, 14 wt %, 15 wt %, 16 wt %, 17 wt %, 18 wt %, 19 wt %, or 20 wt %, or within a range between any two of the values described herein.

Further, the amount of the binder based on the total weight of the binder and silver nanoparticles can range from 4 wt % to 45 wt %, or 4.5 wt % to 40 wt %, or 5 wt % to 35 wt %. For example, based on the total weight of the binder and silver nanoparticles, the amount of the binder can be 4 wt %, 4.5 wt %, 5 wt %, 5.5 wt %, 6 wt %, 7.5 wt %, 10 wt %, 12.5 wt %, 15 wt %, 17.5 wt %, 20 wt %, 22.5 wt %, 25 wt %, 27.5 wt %, 30 wt %, 32.5 wt %, or 35 wt %, or within a range between any two of the values described herein. If the amount of the binder is within the range above, aggregation of silver nanoparticles may be further prevented and finer pattern feature may be produced. In case where the conductive ink composition undergoes further production process (such as drying or sintering) to produce a conductive structure, the amount of the binder based on the total weight of the binder and silver nanoparticles is preferably not higher than the range above so that sufficient conductivity may be provided.

The conductive ink composition comprises a solvent for the ease of handling. The solvent may be used to uniformly dissolve or disperse other components of the conductive ink composition, or to lower the viscosity of the conductive ink composition.

The type of the solvent may be selected such that it has good compatibility with the silver nanoparticles and the binder. The type of the solvent may also be selected based on the processing conditions, such as pressure-controlled direct printing or EHD printing conditions, or subsequent drying or sintering conditions, if any. The solvent can be used as a single component solvent or as a mixed solvent of two or more components.

In an embodiment of the present disclosure, the solvent can be alkoxy alcohol or alkoxy ester. Examples of alkoxy alcohol or alkoxy ester include but are not limited to ethylene glycol monomethyl ether, diethylene glycol monomethyl ether, triethylene glycol monomethyl ether, polyethylene glycol monomethyl ether, ethylene glycol monopropyl ether, diethylene glycol monopropyl ether, ethylene glycol monobutyl ether, diethylene glycol monobutyl ether (also referred to as butyl carbitol), triethylene glycol monobutyl ether, ethylene glycol monoisobutyl ether, ethylene glycol monohexyl ether, diethylene glycol monohexyl ether, ethylene glycol mono-2-ethylhexyl ether, and diethylene glycol mono-2-ethylhexyl ether.

It is found that in some cases, polyol such as glycerol and ethylene glycol may be not quite compatible with some silver nanoparticle slurries or modified silver nanoparticles, and it is adverse to subsequent operations, particularly in EHD printing operations. Therefore, in an embodiment of the present disclosure, it is preferable that the solvent does not comprise polyol. In an embodiment of the present disclosure, the conductive ink composition does not comprise water.

The amount of the solvent can range from 4.9 wt % to 79.9 wt %, or 10 wt % to 75 wt %, or 25 wt % to 65 wt %, based on a total weight of the conductive ink composition. For example, based on the total weight of the conductive ink composition, the amount of the solvent can be 4.9 wt %, 5 wt %, 10 wt %, 15 wt %, 20 wt %, 25 wt %, 30 wt %, 35 wt %, 40 wt %, 45 wt %, 50 wt %, 55 wt %, 60 wt %, 65 wt %, 70 wt %, 75 wt %, or 79.9 wt %, or within a range between any two of the values described herein.

The conductive ink composition may further comprise optional components to adaptively improve the physical properties, chemical properties or processibility of the conductive ink composition. Examples of the optional components include but are not limited to additives such as adhesion promoters, coupling agents, rheology modifiers, dispersants, surfactants, fusion promoters and fluxing agents.

### Properties of Conductive Ink Composition

The conductive ink composition of the present disclosure has rheological properties which may be suitable for pressure-controlled direct printing, particularly suitable for EHD printing.

Specifically, the present disclosure applies a texture test and uses the measured stringiness as an identification for a rheological property suitable for EHD printing. The texture test is conducted under the following conditions: immersing a probe with a diameter of 1 cm vertically into the conductive ink composition to a depth of 1 mm beneath the surface of the conductive ink composition, withdrawing the probe vertically at a speed of 1 mm/s, and defining stringiness as the maximum distance from the surface of the conductive ink composition at which a force exerted on the probe is 0 g.

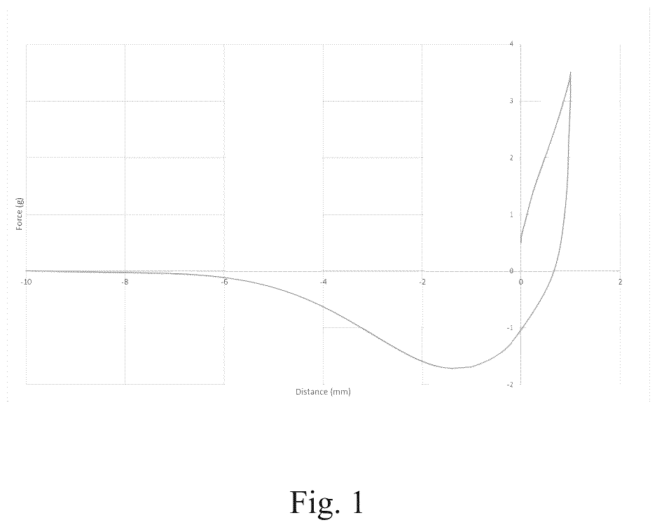

FIG. 1 is an exemplary force-distance diagram for the texture test according to the present disclosure. In the diagram, the vertical axis shows the force in gram, wherein positive values mean that the force is exerted upwardly onto the probe while negative values mean that the force is exerted downwardly onto the probe; and the horizontal axis shows the distance in mm, wherein positive values mean that the front end of the probe is beneath the surface and the probe is immersed in the conductive ink composition while negative value mean that the probe is above the surface. As shown in the diagram, as the probe is immersed into the conductive ink, the force exerted upwardly on the probe gradually becomes greater in magnitude which comes from a resistance force of the conductive ink composition. As the probe is withdrawn from the conductive ink composition, the force becomes smaller in magnitude and eventually changes direction from exerted upwardly to downwardly on the probe. As the probe is pulled out, a portion of conductive ink composition is remained and attached onto the probe in form of a filament and continues to exert force downwardly on the probe. As the distance above the surface increases, the filament becomes thinner and the force exerted on the probe decreases. When the force exerted on the probe reaches 0 g, it is deemed that the filament essentially breaks, and the corresponding distance is defined as stringiness.

When subjected to the texture test above, the conductive ink composition has a stringiness of at least 5 mm, or 5 mm to 30 mm, or 5 mm to 20 mm. For example, the stringiness of the conductive ink composition can be 5 mm, 5.5 mm, 6 mm, 6.5 mm, 7 mm, 7.5 mm, 8 mm, 8.5 mm, 9 mm, 9.5 mm, 10 mm, 10.5 mm, 11 mm, 11.5 mm, 12 mm, 12.5 mm, 13 mm, 13.5 mm, 14 mm, 14.5 mm, 15 mm, 15.5 mm, 16 mm, 16.5 mm, 17 mm, 17.5 mm, 18 mm, 18.5 mm, 19 mm, 20 mm, 21 mm, 22 mm, 23 mm, 24 mm, 25 mm, 26 mm, 27 mm, 28 mm, 29 mm, or 30 mm, or within a range between any two of the values described herein. It is found that when the stringiness of the conductive ink composition is within the range above, good operability and printability can be provided, and the conductive ink composition can be aligned in a desired shape after being ejected onto a substrate. On the other hand, if the stringiness of the conductive ink is outside of the range above, operability and printability may deteriorate. In particular, if the stringiness of the conductive ink composition is lower than the range above, it may not be able to produce filaments or fibers on a substrate, or the fibers ejected on the substrate may not be in a desired shape or not align in a desired manner.

In the premise that the stringiness of the conductive ink composition is at least 5 mm, the conductive ink composition may have other rheological properties/behavior as desired. For example, in an embodiment of the present disclosure, the conductive ink composition has a viscosity of 2,000 to 12,000 cPs, or 3,000 to 10,000 cPs, or 5,000 to 9,000 cPs, measured at 25° C. and a shear rate of 85 s¹.

### Preparation of Conductive Ink Composition

The conductive ink composition of the present disclosure can be prepared by dispersing silver nanoparticles in a solution of a binder. In general, a binder may be mixed with a solvent to form a solution first, and then silver nanoparticles or a silver nanoparticle slurry may be added to the solution and mixed sufficiently to provide a conductive ink solution. The mixing processes can be performed stepwise to lower the likelihood of aggregation occurrence. Exemplary preparation methods of the conductive ink composition are provided in the Example section below.

### Wiring Pattern

The conductive ink composition of the present disclosure can be applied to various fields to provide various products. One application of the conductive ink composition of particular interest is to form a wiring pattern. Therefore, the present disclosure also provides a wiring pattern, which is manufactured from the aforementioned conductive ink composition.

The method for manufacturing the wiring pattern is not particularly limited. For example, in an embodiment of the present disclosure the wiring pattern may be manufactured by pressure-controlled direct printing of the conductive ink composition onto a substrate. In another embodiment of the present disclosure, the wiring pattern is manufactured by electrohydrodynamic (EHD) printing. The pattern feature (such as pitch) of the wiring pattern may be adjusted depending on the desired circuit designs or practical needs.

### EXAMPLES

Hereinafter, some examples are provided to illustrate the present disclosure. These examples are provided for illustrative purpose only and are not intended to limit the scope of the present disclosure.

### Conductive Ink Composition

The raw materials used in the Examples and Comparative Examples were listed in Table 1 below.

TABLE 1

| | Model name and | |
|---|---|---|
| Raw material | manufacturer | Description |
| Silver nanoparticle | SDU-005, | Containing 90.9 wt % of |
| slurry | available | silver nanoparticles and 9.1 |
| | from DOWA | wt % of butyl carbitol, |
| | | wherein the silver |
| | | nanoparticles have an |
| | | average diameter of 130 nm |
| Polyvinylpyrrolidone | Available from | Used as binder, having a |
| (PVP) | Thermo-Fischer | weight average molecular |
| | | weight of 1,300,000 |
| Butyl carbitol | Available from | Used as solvent |
| | Alfa Chemistry | |

### Preparation of Polyvinylpyrrolidone (PVP) Solution

A 20 wt % PVP solution was prepared by using an overhead mechanical stirrer in a 1 L vessel jacketed with a 4 C coolant. First, 240 g of butyl carbitol were added to the vessel. 60 g of polyvinylpyrrolidone (PVP) were weighed in a tray. To prevent PVP aggregation, 10 g of PVP were added slowly every 10 min until a total 60 g of PVP were present in the solution.

The solution was stirred for 4 h until PVP was fully dissolved.

### Example E1

20 g of a silver nanoparticle slurry were weighted in a vial. A total of 4.8 g of the 20 wt % PVP solution prepared above and 1.9 g of butyl carbitol were then stepwise added to the vial and mixed using a mixer (model number: ARE-500; available from Thinky). The steps were: adding 1 g of the 20 wt % PVP solution and mixing at 1000 rpm for 60 s twice, adding 2 g of the 20 wt % PVP solution and mixing at 1000 rpm for 60 s twice, adding 1.8 g of the 20 wt % PVP solution and mixing at 1000 rpm for 60 s twice, and adding 1.9 g of butyl carbitol and mixing at 1000 rpm for 60 s twice. After the adding and mixing steps were completed, the conductive ink composition of Example E1 was obtained.

### Example E2

20 g of a silver nanoparticle slurry were weighted in a vial. A total of 10.2 g of the 20 wt % PVP solution prepared above were then stepwise added to the vial and mixed using a mixer (model number: ARE-500; available from Thinky). The steps were: adding 1 g of the 20 wt % PVP solution and mixing at 1000 rpm for 60 s twice, adding 2 g of the 20 wt % PVP solution and mixing at 1000 rpm for 60 s twice, adding 7.2 g of the 20 wt % PVP solution and mixing at 1000 rpm for 60 s twice. After the adding and mixing steps were completed, the conductive ink composition of Example E2 was obtained.

### Example E3

20 g of a silver nanoparticle slurry were weighted in a vial. A total of 16.1 g of the 20 wt % PVP solution prepared above were then stepwise added to the vial and mixed using a mixer (model number: ARE-500; available from Thinky). The steps were: adding 1 g of the 20 wt % PVP solution and mixing at 1000 rpm for 60 s twice, adding 2 g of the 20 wt % PVP solution and mixing at 1000 rpm for 60 s twice, adding 13.1 g of the 20 wt % PVP solution and mixing at 1000 rpm for 60 s twice. After the adding and mixing steps were completed, the conductive ink composition of Example E3 was obtained.

### Example E4

20 g of a silver nanoparticle slurry were weighted in a vial. A total of 22.8 g of the 20 wt % PVP solution prepared above were then stepwise added to the vial and mixed using a mixer (model number: ARE-500; available from Thinky). The steps were: adding 1 g of the 20 wt % PVP solution and mixing at 1000 rpm for 60 s twice, adding 2 g of the 20 wt % PVP solution and mixing at 1000 rpm for 60 s twice, adding 19.8 g of the 20 wt % PVP solution and mixing at 1000 rpm for 60 s twice. After the adding and mixing steps were completed, the conductive ink composition of Example E4 was obtained.

### Example E5

20 g of a silver nanoparticle slurry were weighted in a vial. A total of 49 g of the 20 wt % PVP solution prepared above were then stepwise added to the vial and mixed using a mixer (model number: ARE-500; available from Thinky). The steps were: adding 1 g of the 20 wt % PVP solution and mixing at 1000 rpm for 60 s twice, adding 2 g of the 20 wt % PVP solution and mixing at 1000 rpm for 60 s twice, adding 46 g of the 20 wt % PVP solution and mixing at 1000 rpm for 60 s twice. After the adding and mixing steps were completed, the conductive ink composition of Example E5 was obtained.

### Comparative Example CE1

20 g of a silver nanoparticle slurry were weighted in a vial. Then, 0.42 g of butyl carbitol were added to the vial and mixed using a mixer (model number: ARE-500; available from Thinky) at 1000 rpm for 60 s twice, and the conductive ink composition of Comparative Example CE1 was obtained. Note that in Comparative Example CE1, no PVP was added.

### Comparative Example CE2

20 g of a silver nanoparticle slurry were weighted in a vial. A total of 2.9 g of the 20 wt % PVP solution prepared above and 7.4 g of butyl carbitol were then stepwise added to the vial and mixed using a mixer (model number: ARE-500; available from Thinky). The steps were: adding 1 g of the 20 wt % PVP solution and mixing at 1000 rpm for 60 s twice, adding 1.9 g of the 20 wt % PVP solution and mixing at 1000 rpm for 60 s twice, and adding 7.4 g of butyl carbitol and mixing at 1000 rpm for 60 s twice. After the adding and mixing steps were completed, the conductive ink composition of Comparative Example CE2 was obtained.

The components used in the Examples and Comparative Examples are summarized in Table 2 below.

TABLE 2

| | | E1 | E2 | E3 | E4 | E5 | CE1 | CE2 |
|---|---|---|---|---|---|---|---|---|
| wt % based on total | Silver nanoparticles | 68.1 | 60.2 | 50.4 | 42.5 | 26.3 | 89 | 60 |
| weight of conductive | Binder | 3.6 | 6.8 | 8.9 | 10.6 | 14.2 | 0 | 1.9 |
| ink composition | Solvent | 28.3 | 33 | 40.7 | 46.9 | 59.5 | 11 | 38.1 |

| | | | | | | | |
|---|---|---|---|---|---|---|---|
| wt % of binder based on total weight of | 5 | 10 | 15 | 20 | 35 | 0 | 3 |
| silver nanoparticles and binder | | | | | | | |

The conductive ink composition of Examples E1-E5 and Comparative Examples CE1-CE2 were tested according to the following methods and the results are shown in Table 3.

### Test Methods

### [Stringiness]

The stringiness of the conductive ink composition is measured using a texture analyzer (TA.XTplusC, available from Stable Micro Systems). First, the conductive ink composition is filled into a container with a dimension of 3.5 cm in diameter×0.3 cm in height. A probe, which is a stainless steel cylinder with a diameter of 1 cm, is immersed vertically into the conductive ink composition to a depth of 1 mm beneath the surface of the conductive ink composition. The position of the probe is then maintained at 1 mm beneath the surface for a duration of 10 seconds. Thereafter, the probe is withdrawn vertically at a speed of 1 mm/s while the force exerted on the probe is continuously recorded. The stringiness is defined as the maximum distance (in mm) from the surface of the conductive ink composition at which the recorded force exerted on the probe is 0 g.

### [Viscosity]

The viscosity of the conductive ink composition is measured by a rheometer (Waters, Discovery Hybrid Rheometer-2, available from TA Instruments) at 25° C. and a shear rate of 85 s⁻¹. The unit for viscosity is cP.

### [Operability]

The operability of the conductive ink composition is evaluated by drawing the conductive ink composition to a filament of a predetermined length and recording the duration until the filament breaks. First, the conductive ink composition is filled into a container with a dimension of 3.5 cm in diameter×0.3 cm in height. A probe, which is a stainless steel cylinder with a diameter of 1 cm, is immersed vertically into the conductive ink composition to a depth of 1 mm beneath the surface of the conductive ink composition. The position of the probe is then maintained at 1 mm beneath the surface for a duration of 10 seconds. Thereafter, the probe is withdrawn vertically at a speed of 10 mm/s such that a portion of conductive ink composition remained and attached to the probe. The drawing continues at 10 mm/s until the tip of the probe reaches 10 mm above the surface, that is, until a filament of 10 mm is drawn. The probe is then held at 10 mm above the surface and the duration until the filament breaks is recorded. A longer duration indicates a better operability of the conductive ink composition.

### [Printability]

The printability of the conductive ink composition is evaluated by subjecting the conductive ink composition to EHD printing. The EHD printing is performed using an EHD printer (model number: MX2, available from ENJET) to print the conductive ink composition on a glass substrate with the goal to form parallel fibers on the substrate. The nozzle used has an inner diameter of 25 m and an outer diameter of 55 m and is set at a distance of 100 m apart from the substrate. The conductive ink composition is loaded and then pumped through the nozzle and driven by a voltage of 1 kV, while the substrate is moved at a speed of 100 mm/s, thereby forming a printed pattern (a wiring pattern) on the substrate.

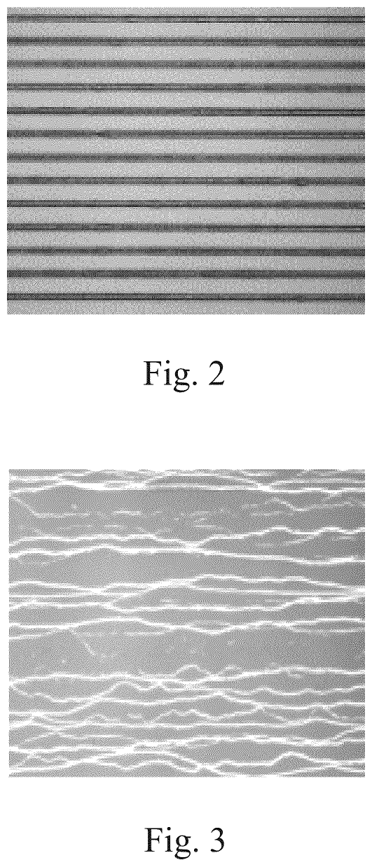

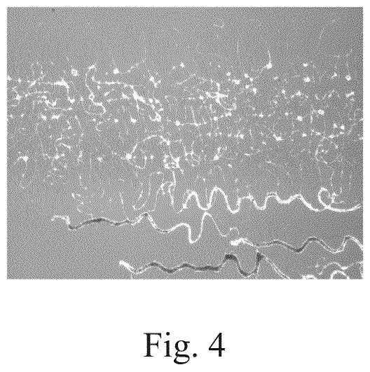

The morphology of the printed pattern is observed under an optical microscope (OM) installed on the EHD printer. The result can be generally categorized into “well-aligned fibers”, “poor-aligned fibers” and “no fiber”. FIG. 2 is a representative OM result of “well-aligned fibers” after EHD printing, where the fibers are aligned parallelly with uniform pitch. If such “well-aligned fibers” are formed, the result is recorded as “∘”, indicating good printability. FIG. 3 is a representative OM result of “poor-aligned fibers” after EHD printing, where the fibers are randomly formed in a wavy shape and intersect with one another. If such “poor-aligned fibers” are formed, the result is recorded as “x”, indicating poor printability. FIG. 4 is a representative OM result of “no fiber” after EHD printing, where no continuous line-like feature can be observed. If such “no fiber” is formed, the result is recorded as “n”, indicating the worst printability.

TABLE 3

| | E1 | E2 | E3 | E4 | E5 | CE1 | CE2 |
|---|---|---|---|---|---|---|---|
| Stringiness (mm) | 6.2 | 9.1 | 12.2 | 16.1 | 14.7 | 3.2 | 4.0 |
| Viscosity (cP) | 5615 | 6213 | 8536 | 7045 | 5514 | 6413 | 5104 |
| Operability (s) | 6 | 10 | 28 | 35 | 17 | ~0 | ~0 |
| Printability | ∘ | ∘ | ∘ | ∘ | ∘ | n | x |

As shown in Table 3, the conductive ink compositions of Examples E1-E5 of the present disclosure each have a stringiness of at least 5 mm. As a result, these conductive ink compositions have good operability and printability. In contrast, the conductive ink compositions CE1-CE2 each have a stringiness of less than 5 mm and result in poor operability and printability.

While some embodiments are provided in the specification, they are only illustrative of the present disclosure and are not intended to limit the protection scope of the present disclosure. Persons skilled in the art may proceed with a variety of modifications based on the disclosure as described without departing from the principle thereof. The protection scope of the present disclosure is as defined in the following claims.

What is claimed is:

1. A conductive ink composition, which comprises:
(A) 20 wt % to 95 wt % of silver nanoparticles;
(B) 0.1 wt % to 20 wt % of a binder; and
(C) 4.9 wt % to 79.9 wt % of a solvent;
wherein the wt % is based on a total weight of the conductive ink composition;
wherein the conductive ink composition has a stringiness of at least 5 mm when subjected to a texture test; and
wherein the texture test is conducted under the following conditions:
immersing a probe with a diameter of 1 cm vertically into the conductive ink composition to a depth of 1 mm beneath a surface of the conductive ink composition,
withdrawing the probe vertically at a speed of 1 mm/s, and
defining stringiness as a maximum distance from the surface of the conductive ink composition at which a force exerted on the probe is 0 g.

2. The conductive ink composition of claim 1, wherein the conductive ink composition has a viscosity of 2,000 to 12,000 cPs measured at 25° C. and a shear rate of 85 s⁻¹.

3. The conductive ink composition of claim 1, wherein the silver nanoparticles (A) have an average diameter of 20 nm to 400 nm.

4. The conductive ink composition of claim 1, wherein the binder (B) is selected from the group consisting of poly(vinyl acetate), poly(vinyl alcohol) (PVA), polydioxanone (PDO), polyacrylamide (PAM), poly(glycolic acid) (PGA), poly-(ε-caprolactone) (PCL), poly(L-lactic acid) (PLLA), polyurethane (PU), polyacrylate, polyvinylpyrrolidone (PVP), poly(vinyl alcohol-co-ethylene), polyethylene glycol (PEG), poly(tetramethylene ether) glycol (PTMEG), ethyl cellulose (EC), cellulose acetate, hydroxypropylmethyl cellulose (HPMC), polyvinyl butyral (PVB), and combinations thereof.

5. The conductive ink composition of claim 1, wherein the solvent (C) is alkoxy alcohol or alkoxy ester.

6. The conductive ink composition of claim 1, wherein based on a total weight of the binder (B) and silver nanoparticles (A), the amount of the binder (B) is 4 wt % to 45 wt %.

7. A wiring pattern, which is manufactured from the conductive ink composition of claim 1.

8. The wiring pattern of claim 7, which is manufactured by electrohydrodynamic (EHD) printing.
